(19) United States
(12) Patent Application Publication
(10) Pub. No.: US 2026/0045293 A1
(43) Pub. Date: Feb. 12, 2026

(54) MEMORY DEVICES CONTROLLING OPERATION TIMING BASED ON INTERNAL TEMPERATURE

(71) Applicant: SK hynix Inc., Icheon-si Gyeonggi-do (KR)

(72) Inventor: Choung Ki SONG, Icheon-si Gyeonggi-do (KR)

(73) Assignee: SK hynix Inc., Icheon-si Gyeonggi-do (KR)

(21) Appl. No.: 18/910,730

(22) Filed: Oct. 9, 2024

(30) Foreign Application Priority Data
Aug. 6, 2024 (KR) 10-2024-0104953

(51) Int. Cl. G11C 11/4076; H01L 25/065; H01L 25/18; H10B 80/00

(52) U.S. Cl. CPC G11C 11/4076; H01L 25/0657; H01L 25/18; H10B 80/00; H01L 2225/06513; H01L 2225/06541; H01L 2225/06586

(57) ABSTRACT

A memory device includes a memory chip stacked over a base chip. The base chip includes a temperature control circuit configured to control, based on information including an internal temperature of the memory device, at least one of a time between consecutive column commands when consecutive column operations are performed and a time between consecutive row commands when consecutive row operations are performed.

### CROSS-REFERENCE TO RELATED APPLICATIONS

The present application claims priority under 35 U.S. C. § 119(a) to Korean Patent Application No. 10-2024-0104953, filed in the Korean Intellectual Property Office on Aug. 6, 2024, the entire contents of which application is incorporated herein by reference.

### BACKGROUND

### 1. Technical Field

The present disclosure relates to semiconductor memory devices, including but not limited to controlling operation timing.

### 2. Related Art

Recently, stacked memory systems such as high bandwidth memory (HBM) devices are used in a wide range of applications due to their excellent bandwidth. Unlike conventional memory systems that use parallel data buses, the stacked memory system includes a stacked memory device including a base chip and a memory chip interconnected by through silicon vias (TSVs). The stacked memory device includes a physical interface, such as a physical layer for communication with a processor. The physical layer is designed for high-speed data transmission and efficient communication.

### SUMMARY

In an embodiment, a memory device may include a memory chip stacked over a base chip. The base chip may include a temperature control circuit configured to control, based on information including an internal temperature of the memory device, a time between consecutive column commands when consecutive column operations are performed.

In an embodiment, a memory device may include a memory chip stacked over a base chip. The base chip may include a temperature control circuit configured to control, based on information including an internal temperature of the memory device, a time between consecutive row commands when consecutive row operations are performed.

In an embodiment, a memory device may include a memory chip stacked over a base chip. The base chip may include a temperature control circuit including a first selector and a second selector. The first selector may be configured to control, based on information including an internal temperature of the memory device, a read time between consecutive read commands when consecutive read operations are performed. The second selector may be configured to control, based on information including the internal temperature of the memory device, a write operation time between consecutive write commands when consecutive write operations are performed.

In an embodiment, a method may include determining an internal temperature for a memory device including a memory chip stacked with a base chip, identifying a time interval between consecutive operation commands based on the internal temperature, and controlling timing between operation commands for the memory device based on the time interval during operation of the memory device.

### BRIEF DESCRIPTION OF THE DRAWINGS

FIG. 1 is a block diagram illustrating a memory device according to an embodiment of the present disclosure.

FIG. 2 illustrates a temperature control circuit according to an embodiment of the present disclosure.

FIG. 3 illustrates operation timing of a temperature control circuit according to an embodiment of the present disclosure.

FIG. 4 illustrates a temperature control circuit according to an embodiment of the present disclosure.

FIG. 5 illustrates a temperature control circuit according to an embodiment of the present disclosure.

FIG. 6 illustrates a temperature control circuit according to an embodiment of the present disclosure.

FIG. 7 is a block diagram illustrating a stacked memory system according to an embodiment of the present disclosure.

### DETAILED DESCRIPTION

Terms such as “first” and “second” are used to distinguish between various elements and do not imply size, order, priority, quantity, or importance of the elements. For example, a first element may be referred to as a second element in one example, and the second element may be referred to as a first element in another example.

When an element is referred to as “connected” to another element, the elements may be connected directly or through one or more intervening elements between the elements. When two elements are referred to as “directly connected” one element is directly connected to the other element without an intervening element between the two elements.

Terms such as “over,” “on,” “inside,” “higher,” “high,” “low,” “left,” “right,” “column,” “row,” “level,” and other terms implying relative spatial relationship or orientation are utilized only for the purpose of ease of description or reference to a drawing and are not otherwise limiting.

The term “bit set” includes a combination of logic levels of bits included in a signal. When the logic level of the bits included in the signal is changed, the bit set of the signal is different. For example, when the signal includes a first combination of two bits, the logic bit set of the signal mis a first bit set, and when the signal includes a second combination of two bits, the bit set of the signal is a second bit set.

Embodiments of the present disclosure are described in detail with reference to the accompanying drawings. Specific structural or functional descriptions of embodiments are provided as examples for illustrative purposes to describe concepts that are disclosed in the present application. Examples or embodiments in accordance with the concepts may be carried out in various forms, and the scope of the present disclosure is not limited to the examples or embodiments described in this specification.

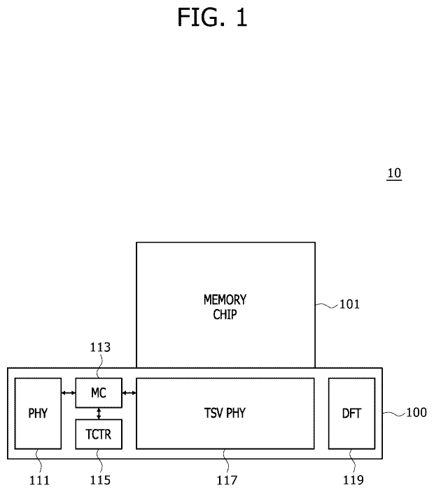

FIG. 1 is a block diagram illustrating a memory device 10 according to an embodiment of the present disclosure.

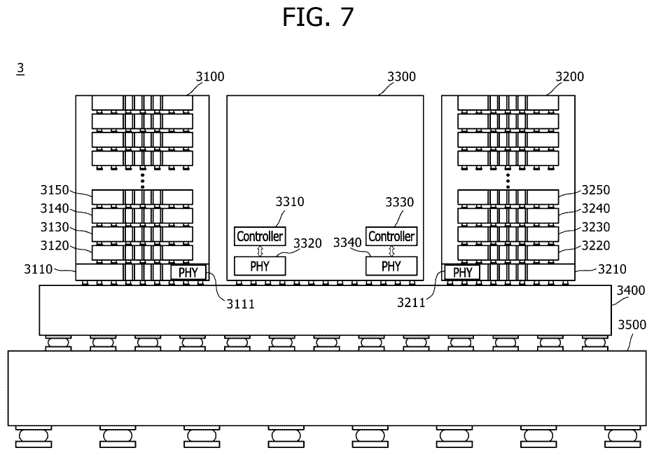

As shown in FIG. 1, the memory device 10 includes a base chip 100 and a memory chip 101. The memory chip 101 is stacked over or on the base chip 100. The memory chip 101 includes a plurality of slice chips, for example, 3120, 3130, 3140, 3150, 3220, 3230, 3240, and 3250 in FIG. 7. The quantity L of the slice chips may be, for example, one of 4, 8, and 12, where L is a positive integer. The present disclosure is not limited to these examples. Through-silicon vias (“TSVs”) are formed in the memory chip 101 and the base chip 100. A TSV is a structure that provides electrical connection by extending through the memory chip 101 and the base chip 100 and transmits signals and data, advantageously at high speed, between the memory chip 101 and the base chip 100.

The base chip 100 includes a physical channel (PHY) 111, a memory controller (MC) 113, a temperature control circuit (TCTR) 115, a TSV physical channel (TSV PHY) 117, and a test circuit (DFT) 119.

The physical channel 111 controls generation, transmission, and reception of signals or data, and physical connection between the memory device 10 and a processor, for example 3300 in FIG. 7, such as a CPU or a GPU. The physical channel 111 converts data into electrical, optical, or electromagnetic signals, and vice versa, converts the converted signals back into data between the processor and the memory device 10. In addition, the physical channel 111 manages the physical medium and bandwidth for transmission of signals or data, synchronizes the processor and the memory device 10, and detects errors occurring in the signals and data.

The memory controller 113 manages data transmission between the processor and the memory device 10. The memory controller 113 may be configured to improve the efficiency of the memory hierarchy and increase the performance of a memory system. The memory controller 113 converts logical addresses generated during a process into physical addresses, controls operation of storing data in the memory chip 101, and controls operation of outputting data stored in the memory chip 101. The memory controller 113 controls parallel processing for data to improve the memory bandwidth, detects and corrects errors in data to improve stability of the memory system, and controls access timing for the memory cells included in the memory chip 101, for example, to ensure efficient communication between the processor and the memory device 10. The memory controller 113 controls the physical channel 111, the temperature control circuit 115, and the TSV physical channel 117.

The temperature control circuit 115 controls operation timing depending on the internal temperature of the memory device 10. The temperature control circuit 115 receives information including the internal temperature of the memory device 10 from a temperature sensor (not shown). A temperature sensor may be located in the base chip 100, may be located in at least one of the slice chips of the memory chip 101, or may be located in both the base chip 100 and the memory chip 101. Operation timing includes a column-to-column delay tCCD that is a first time, including but not limited to a minimum or shortest time, between consecutive column commands when consecutive column operations are performed and a row-to-row delay tRRD that is a second time, including but not limited to a minimum or shortest time, between consecutive row commands when consecutive row operations are performed. The column operation includes a read operation and a write operation, and the row operation includes an active operation. During the row operation, at least one word line connected to the memory cells is selected to access the memory cells, and during the column operation, at least one bit line connected to the memory cells is selected to access the memory cells. In an embodiment, a method includes determining an internal temperature for a memory device including a memory chip stacked with a base chip, identifying a time interval between consecutive operation commands based on the internal temperature, and controlling timing between operation commands for the memory device based on the time interval during operation of the memory device.

The TSV physical channel 117 transmits and receives signals and data through the TSVs connected to the memory chip 101. The TSV physical channel 117 is controlled by the memory controller 113 to transmit data through the TSVs during the write operation for the memory chip 101 and receive data through the TSVs during the read operation for the memory chip 101.

The test circuit 119 performs tests using various techniques to detect defects that may occur during the manufacturing process, shorten test time, and reduce test costs. The tests performed in the test circuit 119 may include built-in self-test BIST, boundary-scan, design-for-debug DfD, error correction code ECC, and the like. BIST is a technique that utilizes embedded test logic inside a chip and performs tests on its own or independently of control from outside the test circuit 119. Boundary-scan is a technique described in the IEEE 1149.1 standard and may be used to test connections through TSVs. DfD is a technique that improves the ease of debugging during the design phase, allowing for rapid diagnosis and resolution of problems that may occur in silicon. ECC is a technique used to ensure the integrity of data stored in memory.

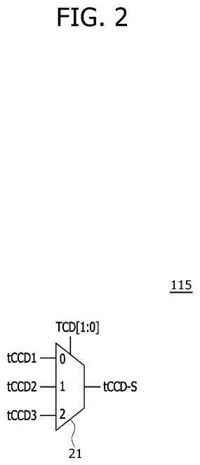

FIG. 2 illustrates a temperature control circuit 115 according to an embodiment of the present disclosure.

As shown in FIG. 2, the temperature control circuit 115 includes a selector 21 that generates a selection operation timing signal tCCD-S, based on a temperature code TCD[1:0], from a first operation timing signal tCCD1, a second operation timing signal tCCD2, and a third operation timing signal tCCD3. The selector 21 receives the first operation timing signal tCCD1 through a first input terminal “0”, receives the second operation timing signal tCCD2 through a second input terminal “1”, and receives the third operation timing signal tCCD3 through a third input terminal “2”. The temperature control circuit 115 receives the temperature code TCD[1:0] from a temperature sensor (not shown) located in at least one of a base chip 100 and a memory chip 101. A bit set including the bits of the temperature code TCD[1:0] corresponds to the internal temperature of a memory device 10. For example, the temperature code TCD[1:0] includes a first bit set “00” that corresponds to a low temperature, such as 40° C., the temperature code TCD[1:0] includes a second bit set “01” that corresponds to a high temperature, such as 70° C., and the temperature code TCD[1:0] includes a third bit set “10” that corresponds to a critical temperature, such as 90° C. When the temperature code TCD[1:0] includes the second bit set “01” indicates that the first bit TCD[0] of the temperature code is at “1” and the second bit TCD[1] of the temperature code is at “0”. In an embodiment, the bit set included in the temperature code TCD[1:0] corresponds to an internal temperature range for the memory device 10. For example, the temperature code TCD[1:0] including the first bit set “00” corresponds to a first temperature range, for example, less than 70° C., the temperature code TCD[1:0] including the second bit set “01” corresponds to a second temperature range, for example, between 70° C. and 90° C., and the temperature code TCD[1:0] including the third bit set “10” corresponds to a third temperature range, for example, 90° C. or higher.

When the temperature code TCD[1:0] including the first bit set is received, the temperature control circuit 115 selects the first operation timing signal tCCD1 received at the first input terminal “0” to output the first operation timing signal tCCD1 as the selection operation timing signal tCCD-S. When the temperature code TCD[1:0] including the second bit set is received, the temperature control circuit 115 selects the second operation timing signal tCCD2 received at the second input terminal “1” to output the second operation timing signal tCCD2 as the selection operation timing signal tCCD-S. When the temperature code TCD[1:0] including the third bit set is received, the temperature control circuit 115 selects the third operation timing signal tCCD3 received at the third input terminal “2” to output the third operation timing signal tCCD3 as the selection operation timing signal tCCD-S. In an embodiment, the first operation timing signal tCCD1 is generated based on tCCD that is a base timing value or the period of time or interval between consecutive column commands or time between performing consecutive column operations, the second operation timing signal tCCD2 is generated based on 1.5 times the base timing value or 1.5 times tCCD as the time between consecutive column commands, and the third operation timing signal tCCD3 is generated based on 2 times the base timing value or 2 times tCCD as the time between consecutive column commands. The present disclosure is not limited to these examples.

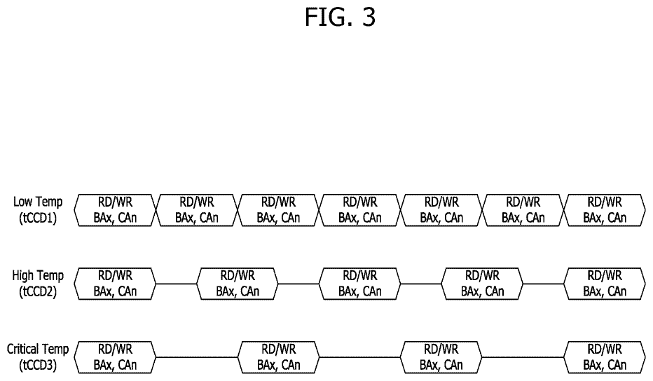

FIG. 3 illustrates operation timing of the temperature control circuit 115, for example, as shown in FIG. 2.

As shown in the example FIG. 3, when the temperature control circuit 115 detects a low temperature, the temperature control circuit 115 selects the first operation timing signal tCCD1 as the selection operation timing signal tCCD-S. The first operation timing signal tCCD1 is generated at intervals of tCCD, which is the base timing value between consecutive column commands when consecutive column operations are performed. When the temperature control circuit 115 detects a high temperature, the temperature control circuit 115 selects the second operation timing signal tCCD2 as the selection operation timing signal tCCD-S. The second operation timing signal tCCD2 is generated at intervals of 1.5 times the base timing value tCCD. When the temperature control circuit 115 detects a critical temperature, the temperature control circuit 115 selects the third operation timing signal tCCD3 as the selection operation timing signal tCCD-S. The third operation timing signal tCCD3 is generated at intervals of 2 times the base timing value tCCD. At the low temperature, the consecutive column commands for the consecutive column operations, for example, read commands RDs for read operations or write commands WTs for write operations are input according to the first operation timing signal tCCD1 at an interval of the base timing value tCCD. At the high temperature, the read commands RDs or the write commands WTs are input according to the second operation timing signal tCCD2 at an interval of 1.5 times the base timing value tCCD. At the critical temperature, the read commands RDs or the write commands WTs are input according to the third operation timing signal tCCD3 at an interval of twice the base timing value tCCD. BAx indicates bank addresses for selecting banks, and CAn indicates column addresses for selecting column lines during read operations or write operations.

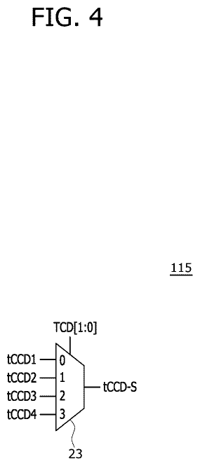

FIG. 4 illustrates a temperature control circuit 115 according to an embodiment of the present disclosure.

As shown in FIG. 4, the temperature control circuit 115 includes a selector 23 that generates a selection operation timing signal tCCD-S, based on a temperature code TCD[1:0], from a first operation timing signal tCCD1, a second operation timing signal tCCD2, a third operation timing signal tCCD3, and a fourth operation timing signal tCCD4. The selector 23 receives the first operation timing signal tCCD1 through a first input terminal “0”, receives the second operation timing signal tCCD2 through a second input terminal “1”, receives the third operation timing signal tCCD3 through a third input terminal “2”, and receives the fourth operation timing signal tCCD4 through a fourth input terminal “3”. A bit set including the bits of the temperature code TCD[10] corresponds to the internal temperature of a memory device 10. For example, the temperature code TCD[1:0] includes a first bit set “00” that corresponds to a first temperature, the temperature code TCD[1:0] includes a second bit set “01” that corresponds to a second temperature, the temperature code TCD[1:0] includes a third bit set “10” that corresponds to a third temperature, and the temperature code TCD[1:0] includes a fourth bit set “11” that corresponds to a fourth temperature. The first temperature, the second temperature, the third temperature, and the fourth temperature may be determined in various different ways depending on the embodiment. In an embodiment, the bit set including the bits of the temperature code TCD[1:0] corresponds to an internal temperature range for the memory device 10. For example, the temperature code TCD[1:0] includes the first bit set “00” that corresponds to a first temperature range, the temperature code TCD[1:0] includes the second bit set “01” that corresponds to a second temperature range, the temperature code TCD[1:0] includes the third bit set “10” that corresponds to a third temperature range, and the temperature code TCD[1:0] includes the fourth bit set “11” that correspond to a fourth temperature range. The first temperature range, the second temperature range, the third temperature range, and the fourth temperature range may be determined in various different ways depending on the embodiment.

When the temperature code TCD[1:0] including the first bit set is received, the temperature control circuit 115 selects the first operation timing signal tCCD1 received at the first input terminal “0” to output the first operation timing signal tCCD1 as the selection operation timing signal tCCD-S. When the temperature code TCD[1:0] including the second bit set is received, the temperature control circuit 115 selects the second operation timing signal tCCD2 received at the second input terminal “1” to output the second operation timing signal tCCD2 as the selection operation timing signal tCCD-S. When the temperature code TCD[1:0] including the third bit set is received, the temperature control circuit 115 selects the third operation timing signal tCCD3 received at the third input terminal “2” to output the third operation timing signal tCCD3 as the selection operation timing signal tCCD-S. When the temperature code TCD[1:0] including the fourth bit set is received, the temperature control circuit 115 selects the fourth operation timing signal tCCD4 received at the fourth input terminal “3” to output the fourth operation timing signal tCCD4 as the selection operation timing signal tCCD-S. In this example, the first operation timing signal tCCD1 is generated based on tCCD that is the base timing value or the period of time between consecutive column commands or time between performing consecutive column operations, the second operation timing signal tCCD2 is generated based on 1.5 times the base timing value or 1.5 times tCCD as the time between consecutive column commands, the third operation timing signal tCCD3 is generated based on twice the base timing value or 2 times tCCD as the time between consecutive column commands, and the fourth operation timing signal tCCD4 is generated based on 2.5 times the base timing value or 2.5 times tCCD as the time between consecutive column commands. The present disclosure is not limited to this example.

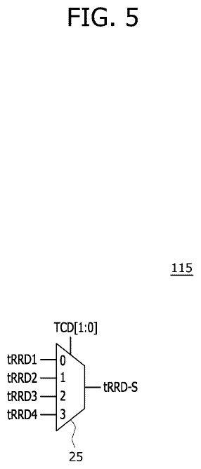

FIG. 5 illustrates a temperature control circuit 115 according to an embodiment of the present disclosure.

Referring to FIG. 5, the temperature control circuit 115 includes a selector 25 that generates a selection operation timing signal tRRD-S, based on a temperature code TCD[1:0], from a first operation timing signal tRRD1, a second operation timing signal tRRD2, a third operation timing signal tRRD3, and a fourth operation timing signal tRRD4. The selector 25 receives the first operation timing signal tRRD1 through a first input terminal “0”, receives the second operation timing signal tRRD2 through a second input terminal “1”, receives the third operation timing signal tRRD3 through a third input terminal “2”, and receives the fourth operation timing signal tRRD4 through a fourth input terminal “3”. A bit set including the bits of the temperature code TCD[1: 0] corresponds to one of an internal temperature of and an internal temperature range for a memory device 10. When the temperature code TCD[1:0] including a first bit set is received, the temperature control circuit 115 selects the first operation timing signal tRRD1 received at the first input terminal “0” to output the first operation timing signal tRRD1 as the selection operation timing signal tRRD-S. When the temperature code TCD[1:0] including a second bit set is received, the temperature control circuit 115 selects the second operation timing signal tRRD2 received at the second input terminal “1” to output the second operation timing signal tRRD2 as the selection operation timing signal tRRD-S. When the temperature code TCD[1:0] including a third bit set is received, the temperature control circuit 115 selects the third operation timing signal tRRD3 received at the third input terminal “2” to output the third operation timing signal tRRD3 as the selection operation timing signal tRRD-S. When the temperature code TCD[1:0] including a fourth bit set is received, the temperature control circuit 115 selects the fourth operation timing signal tRRD4 received at the fourth input terminal “3” to output the fourth operation timing signal tRRD4 as the selection operation timing signal tRRD-S. In this example, the first operation timing signal tRRD1 is generated based on tRRD that is a base timing value or the period of time or interval between consecutive row commands or time between performing consecutive row operations, the second operation timing signal tRRD2 is generated at 1.5 times the base timing value or 1.5 times tRRD as the time between consecutive row commands, the third operation timing signal tRRD3 is generated based on twice the base timing value or 2 times tRRD as the time between consecutive row commands, and the fourth operation timing signal tRRD4 is generated based on 2.5 times the base timing value or 2.5 times tRRD as the time between consecutive row commands. The present disclosure is not limited to these examples.

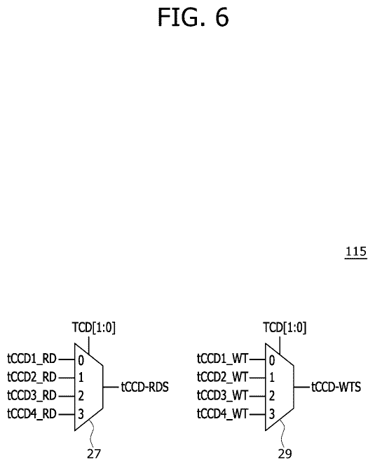

FIG. 6 illustrates a temperature control circuit 115 according to an embodiment of the present disclosure.

As shown in FIG. 6, the temperature control circuit 115 includes a first selector 27 and a second selector 29.

The first selector 27 generates a selection read operation timing signal tCCD-RDS, based on a temperature code TCD[1:0], from a first read operation timing signal tCCD1-RD, a second read operation timing signal tCCD2-RD, a third read operation timing signal tCCD3-RD, and a fourth read operation timing signal tCCD4-RD. The first selector 27 receives the first read operation timing signal tCCD1-RD through a first input terminal “0”, receives the second read operation timing signal tCCD2-RD through a second input terminal “1”, receives the third read operation timing signal tCCD3-RD through a third input terminal “2”, and receives the fourth read operation timing signal tCCD4-RD through a fourth input terminal “3”. When the temperature code TCD[1: 0] including a first bit set is received, the first selector 27 selects the first read operation timing signal tCCD1-RD received at the first input terminal “0” to output the first read operation timing signal tCCD1-RD as the selection read operation timing signal tCCD-RDS. When the temperature code TCD[1:0] including a second bit set is received, the first selector 27 selects the second read operation timing signal tCCD2-RD received at the second input terminal “1” to output the second read operation timing signal tCCD2-RD as the selection read operation timing signal tCCD-RDS. When the temperature code TCD[1:0] including a third bit set is received, the first selector 27 selects the third read operation timing signal tCCD3-RD received at the third input terminal “2” to output the third read operation timing signal tCCD3-RD as the selection read operation timing signal tCCD-RDS. When the temperature code TCD[1:0] including a fourth bit set is received, the first selector 27 selects the fourth read operation timing signal tCCD4-RD received at the fourth input terminal “3” to output the fourth read operation timing signal tCCD4-RD as the selection read operation timing signal tCCD-RDS. In this example, the first read operation timing signal tCCD1-RD is generated based on tCCD that is a base read timing value or the period of time or interval between consecutive read commands or time between performing consecutive read operations, the second read operation timing signal tCCD2-RD is generated based on 1.5 times the base read timing value or 1.5 times tCCD as the time between consecutive read commands, the third read operation timing signal tCCD3-RD is generated based on twice the base read timing value or 2 times tCCD as the time between consecutive read commands, and the fourth read operation timing signal tCCD4-RD is generated based on 2.5 times the base read timing value or 2.5 times tCCD as the time between consecutive read commands. The present disclosure is not limited to this example.

The second selector 29 generates a selection write operation timing signal tCCD-WTS, based on the temperature code TCD[1:0], from a first write operation timing signal tCCD1-WT, a second write operation timing signal tCCD2-WT, a third write operation timing signal tCCD3-WT, and a fourth write operation timing signal tCCD4-WT. The second selector 29 receives the first write operation timing signal tCCD1-WT through a first input terminal “0”, receives the second write operation timing signal tCCD2-WT through a second input terminal “1”, receives the third write operation timing signal tCCD3-WT through a third input terminal “2”, and receives the fourth write operation timing signal tCCD4-WT through a fourth input terminal “3”. When the temperature code TCD[1: 0] including the first bit set is received, the second selector 29 selects the first write operation timing signal tCCD1-WT received at the first input terminal “0” to output the first write operation timing signal tCCD1-WT as the selection write operation timing signal tCCD-WTS. When the temperature code TCD[1:0] including the second bit set is received, the second selector 29 selects the second write operation timing signal tCCD2-WT received at the second input terminal “1” to output the second write operation timing signal tCCD2-WT as the selection write operation timing signal tCCD-WTS. When the temperature code TCD[1:0] including the third bit set is received, the second selector 29 selects the third write operation timing signal tCCD3-WT received at the third input terminal “2” to output the third write operation timing signal tCCD3-WT as the selection write operation timing signal tCCD-WTS. When the temperature code TCD[1:0] including the fourth bit set is received, the second selector 29 selects the fourth write operation timing signal tCCD4-WT received at the fourth input terminal “3” to output the fourth write operation timing signal tCCD4-WT as the selection write operation timing signal tCCD-WTS. In this example, the first write operation timing signal tCCD1-WT is generated based on tCCD that is a base write timing value or the period of time or interval between consecutive write commands or time between performing consecutive write operations, the second write operation timing signal tCCD2-WT is generated based on 1.5 times the base write timing value or 1.5 times tCCD as the time between consecutive write commands, the third write operation timing signal tCCD3-WT is generated based on twice the base write timing value or 2 times tCCD as the time between consecutive write commands, and the fourth write operation timing signal tCCD4-WT is generated based on 2.5 times the base write timing value or 2.5 times tCCD as the time between consecutive write commands. The present disclosure is not limited to this example.

FIG. 7 is a block diagram illustrating a stacked memory system 3 according to an embodiment of the present disclosure. As shown in FIG. 7, the stacked memory system 3 includes a first stacked memory device 3100, a second stacked memory device 3200, a processor 3300, an interposer 3400, and a substrate 3500.

The interposer 3400 is disposed over or on the substrate 3500, and the first stacked memory device 3100, the second stacked memory device 3200, and the processor 3300 are disposed over the interposer 3400. The processor 3300 is disposed between the first stacked memory device 3100 and the second stacked memory 3200. The interposer 3400 electrically connects the substrate 3500, the first stacked memory device 3100, the second stacked memory device 3200, and the processor 3300 to each other. Because the pitch differences between the first stacked memory device 3100, the second stacked memory device 3200, and the processor 3300 are large, the first stacked memory device 3100, the second stacked memory device 3200, and the processor 3300 may be electrically connected through variously formed wires.

The processor 3300 includes a first controller 3310 that controls the first stacked memory device 3100 and a first process interface circuit 3320 that electrically connects the first stacked memory device 3100 to a first controller 3310. The processor 3300 includes a second controller 3330 that controls the second stacked memory device 3200 and a second process interface circuit 3340 that electrically connects the second stacked memory device 3200 to a second controller 3330. The processor 3300 provides signals including commands and addresses that control various internal operations of the first stacked memory device 3100 to the first stacked memory device 3100 through the first process interface circuit 3320 and receives signals from the first stacked memory device 3100 through the first process interface circuit 3320. The processor 3300 provides signals including commands and addresses that control various internal operations of the second stacked memory device 3200 to the second stacked memory device 3200 through the second process interface circuit 3340 and receives signals from the second stacked memory device 3200 through the second process interface circuit 3340.

The first stacked memory device 3100 includes a first base chip 3110 and first slice chips 3120, 3130, 3140, and 3150. The first stacked memory device 3100 may be implemented similarly to the memory device 10 shown in FIG. 1. The first slice chips 3120, 3130, 3140, and 3150 are sequentially stacked over or on the first base chip 3110 and receives various signals from the first base chip 3110 via through-vias. In FIG. 7, the first stacked memory device 3100 as shown includes four first slice chips 3120, 3130, 3140, and 3150, different quantities of slice chips, such as 4 slice chips, 8 slice chips, 12 slice chips, 16 slice chips, and so forth may be arranged and stacked.

The first base chip 3110 includes a first core interface circuit 3111. The first core interface circuit 3111 is configured to communicate with the first processor interface circuit 3320 to receive signals transmitted from the processor 3300 and provide signals generated by the first slice chips 3120, 3130, 3140, and 3150 to the processor 3300. The first base chip 3110 includes a temperature control circuit that controls the operation timing for the first stacked memory device 3100 based on an internal temperature of the memory system 3, such as an internal temperature of the first stacked memory device 3100. The temperature control circuit may be implemented similarly to the temperature control circuit 115 shown in FIG. 1. Alternatively, one or more temperature control circuits may be located elsewhere in the memory system 3.

The second stacked memory device 3200 includes a second base chip 3210 and second slice chips 3220, 3230, 3240, and 3250. The second stacked memory device 3200 may be implemented similarly to the memory device 1 shown in FIG. 1. The second slice chips 3220, 3230, 3240, and 3250 are sequentially stacked over or on the second base chip 3210 to receive various signals from the second base chip 3210 via through-vias. In FIG. 7, the second stacked memory device 3200 as shown includes four second slice chips 3220, 3230, 3240, and 3250, although different quantities of slice chips, such as 4 slice chips, 8 slice chips, 12 slice chips, 16 slice chips, and so forth may be arranged and stacked.

The second base chip 3210 includes a second core interface circuit 3211. The second core interface circuit 3211 is configured to communicate with the second processor interface circuit 3330 to receive signals transmitted from the processor 3300 and provide signals generated by the second slice chips 3220, 3230, 3240, and 3250 to the processor 3300. The second base chip 3210 may include a temperature control circuit that controls the operation timing for the second stacked memory device 3200 based on an internal temperature of the memory system 3, such as an internal temperature of the second stacked memory device 3200. The temperature control circuit may be implemented similarly to the temperature control circuit 115 shown in FIG. 1.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory device comprising:
a memory chip stacked over a base chip;
the base chip comprising a temperature control circuit configured to control, based on information including an internal temperature of the memory device, a time between consecutive column commands when consecutive column operations are performed.

2. The memory device of claim 1, wherein the information including the internal temperature includes a temperature code generated from a temperature sensor located in at least one of the base chip and the memory chip.

3. The memory device of claim 2, wherein one of a plurality of bit sets is included in the temperature code and corresponds to the internal temperature of the memory device.

4. The memory device of claim 2, wherein one of a plurality of bit sets is included in the temperature code and corresponds to an internal temperature range for the memory device.

5. The memory device of claim 1, wherein the temperature control circuit is configured to select, based on a temperature code, one of a first operation timing signal, a second operation timing signal, and a third operation timing signal to output as a selection operation timing signal.

6. The memory device of claim 5, wherein the temperature control circuit is configured to:
select the first operation timing signal to output the first operation timing signal as the selection operation timing signal when the temperature code for a first bit set is received;
select the second operation timing signal to output the second operation timing signal as the selection operation timing signal when the temperature code for a second bit set is received; and
select the third operation timing signal to output the third operation timing signal as the selection operation timing signal when the temperature code for a third bit set is received.

7. The memory device of claim 5, wherein the temperature control circuit is configured to:
receive the first operation timing signal based on a base timing value;
receive the second operation timing signal based on 1.5 times the base timing value; and
receive the third operation timing signal based on twice the base timing value.

8. The memory device of claim 1, wherein the base chip further comprises:
a physical channel that controls generation, transmission, reception, and physical connection of signals and data between a processor and the memory device;
a memory controller configured to manage data transmission between the processor and the memory device;
a through silicon via (TSV) physical channel configured to transmit and receive the signals and data through TSVs connected to the memory chip; and
a test circuit configured to perform tests on the memory chip.

9. The memory device of claim 1, wherein the column operation is a read operation or a write operation.

10. The memory device of claim 1, wherein the temperature control circuit is configured to control, based on the information including the internal temperature, a second time between consecutive row commands when consecutive row operations are performed.

11. The memory device of claim 10, wherein the row operation is an active operation.

12. A memory device comprising:
a memory chip stacked over a base chip; and
the base chip comprising a temperature control circuit configured to control, based on information including an internal temperature of the memory device, a time between consecutive row commands when consecutive row operations are performed.

13. The memory device of claim 12, wherein the information including the internal temperature includes a temperature code generated from a temperature sensor located in at least one of the base chip and the memory chip.

14. The memory device of claim 13, wherein one of a plurality of bit sets is included in the temperature code and corresponds to one of the internal temperature of the memory device and an internal temperature range for the memory device.

15. A memory device comprising:
a memory chip stacked over a base chip;
the base chip comprising a temperature control circuit including:
a first selector configured to control, based on information including an internal temperature of the memory device, a read time between consecutive read commands when consecutive read operations are performed; and
a second selector configured to control, based on information including the internal temperature of the memory device, a write time between consecutive write commands when consecutive write operations are performed.

16. The memory device of claim 15, wherein the information including the internal temperature includes a temperature code generated from a temperature sensor located in at least one of the base chip and the memory chip.

17. The memory device of claim 16, wherein one of a plurality of bit sets is included in the temperature code and corresponds to the internal temperature of the memory device.

18. The memory device of claim 15, wherein the first selector is configured to select, based on a temperature code, one of a first read operation timing signal, a second read operation timing signal, and a third read operation timing signal to output as a selection read operation timing signal.

19. The memory device of claim 15, wherein the second selector is configured to select, based on a temperature code, one of a first write operation timing signal, a second write operation timing signal, and a third write operation timing signal to output as a selection write operation timing signal.

20. The memory device of claim 15, wherein the base chip further comprises:
a physical channel that controls generation, transmission, reception, and physical connection of signals and data between a processor and the memory device;
a memory controller configured to manage data transmission between the processor and the memory device;
a TSV physical channel configured to transmit and receive the signals and data through TSVs connected to the memory chip; and
a test circuit configured to perform tests on the memory chip.

21. A method comprising:
determining an internal temperature for a memory device including a memory chip stacked with a base chip;
identifying a time interval between consecutive operation commands based on the internal temperature; and
controlling timing between operation commands for the memory device based on the time interval during operation of the memory device.
